(19) United States
(12) Patent Application Publication
(10) Pub. No.: US 2003/0066705 A1
(43) Pub. Date: Apr. 10, 2003

(54) Bass reflex acoustical enclosure with two speakers to enhance acoustical performance

(75) Inventor: Wayne Milton Schott, Seymour, TN (US)

Correspondence Address: Corporate Patent Counsel, U.S. Philips Corporation, 580 White Plains Road, Tarrytown, NY, 10591, US

(73) Assignee: KONINKLIJKE PHILIPS ELECTRONICS N.V.

(21) Appl. No.: 09/973,338

(22) Filed: Oct. 9, 2001

(51) Int. Cl. H05K 5/00

(52) U.S. Cl. 181/156; 181/148; 181/160

(57) ABSTRACT

An apparatus and method is disclosed for enhancing the acoustical performance of a dual chamber bass reflex acoustical enclosure. The apparatus of the invention comprises a first speaker placed within a partitioning wall between a first chamber and a second chamber of the acoustical enclosure. The apparatus of the invention also comprises a second speaker placed within an external wall of the first chamber of the acoustical enclosure. The first speaker and the second speaker are electrically connected in phase. The apparatus of the invention extends the low frequency response of the acoustical enclosure to approximately thirty Hertz.

### TECHNICAL FIELD OF THE INVENTION

The present invention is directed to acoustical enclosures, and, in particular, to bass reflex acoustical enclosures of the type having at least one ported acoustical enclosure.

### BACKGROUND OF THE INVENTION

A bass reflex acoustical enclosure is an acoustical enclosure that has at least one port or vent within the walls of the acoustical enclosure. A ported acoustical enclosure in a bass reflex acoustical enclosure forms a resonator for air within the acoustical enclosure. The air within the acoustical enclosure is forced in and out of the port or vent during vibration of a speaker diaphragm located within the acoustical enclosure.

Examples of bass reflex acoustical enclosures are set forth and described in U.S. Pat. No. 4,875,546 issued Oct. 24, 1989 and in U.S. Pat. No. 4,549,631 issued Oct. 29, 1985.

Prior art bass reflex acoustical enclosures are generally able to provide a low frequency response range that extends down to approximately forty Hertz.

To enhance acoustical performance of a bass reflex acoustical enclosure it would be desirable to have a bass reflex acoustical enclosure that has an extended low frequency response range. In particular, it would be desirable to have a bass reflex acoustical enclosure that has a low frequency response range that extends down to approximately thirty Hertz.

### SUMMARY OF THE INVENTION

The present invention generally comprises an apparatus and method for enhancing the acoustical performance of a bass reflex acoustical enclosure.

The apparatus of the present invention comprises a bass reflex acoustical enclosure having an internal speaker mounted within a partitioning wall between a first chamber and a second chamber of the acoustical enclosure. In one advantageous embodiment of the invention, an internal vent connects the first chamber and the second chamber of the acoustical enclosure. The apparatus of the present invention also has an external speaker mounted within an external wall of the first chamber. An external vent allows air from the second chamber to have access to the air outside the acoustical enclosure. The internal speaker and the external speaker are electrically coupled in phase. The operation of the internal speaker and the external speaker provides a low frequency response range for the acoustical enclosure down to approximately thirty Hertz.

It is a primary object of the present invention to provide an apparatus and method to enhance the acoustical performance of a bass reflex acoustical enclosure.

It is another object of the present invention to provide an apparatus and method to enable a bass reflex acoustical enclosure to provide a low frequency response range down to approximately thirty Hertz.

It is a further object of the present invention to provide an apparatus and method for enabling a bass reflex acoustical enclosure to operate with an internal speaker and an external speaker electrically coupled in phase.

The foregoing has outlined rather broadly the features and technical advantages of the present invention so that those skilled in the art may better understand the Detailed Description of the Invention that follows. Additional features and advantages of the invention will be described hereinafter that form the subject of the claims of the invention. Those skilled in the art should appreciate that they may readily use the conception and the specific embodiment disclosed as a basis for modifying or designing other structures for carrying out the same purposes of the present invention. Those skilled in the art should also realize that such equivalent constructions do not depart from the spirit and scope of the invention in its broadest form.

Before undertaking the Detailed Description of the Invention, it may be advantageous to set forth definitions of certain words and phrases used throughout this patent document: the terms “include” and “comprise” and derivatives thereof, mean inclusion without limitation; the term “or,” is inclusive, meaning and/or; the phrases “associated with” and “associated therewith,” as well as derivatives thereof, may mean to include, be included within, interconnect with, contain, be contained within, connect to or with, couple to or with, be communicable with, cooperate with, interleave, juxtapose, be proximate to, be bound to or with, have, have a property of, or the like; and the term “controller,” “processor,” or “apparatus” means any device, system or part thereof that controls at least one operation, such a device may be implemented in hardware, firmware or software, or some combination of at least two of the same. It should be noted that the functionality associated with any particular controller may be centralized or distributed, whether locally or remotely. In particular, a controller may comprise one or more data processors, and associated input/output devices and memory, that execute one or more application programs and/or an operating system program. Definitions for certain words and phrases are provided throughout this patent document. Those of ordinary skill in the art should understand that in many, if not most, instances such definitions apply to prior uses, as well as to future uses, of such defined words and phrases.

### BRIEF DESCRIPTION OF THE DRAWINGS

For a more complete understanding of the present invention, and the advantages thereof, reference is now made to the following descriptions taken in conjunction with the accompanying drawings, wherein like numbers designate like objects, and in which:

FIG. 1 is a schematic diagram of a prior art bass reflex acoustical enclosure having one speaker, one internal vent, and one external vent;

FIG. 2 is a frequency response chart showing the gain of the prior art acoustical enclosure shown in FIG. 1 as a function of frequency;

FIG. 3 is a schematic diagram of a bass reflex acoustical enclosure of an advantageous embodiment of the present invention having two speakers, one internal vent, and one external vent;

FIG. 4 is a circuit diagram of a model of the bass reflex acoustical enclosure of the present invention shown in FIG. 3;

FIG. 5 is a frequency response chart showing the gain of the bass reflex acoustical enclosure of the present invention shown in FIG. 3 as a function of frequency; and

FIG. 6 is a schematic diagram of a bass reflex acoustical enclosure of an alternate advantageous embodiment of the present invention having two speakers, no internal vent, and one external vent.

### DETAILED DESCRIPTION OF THE INVENTION

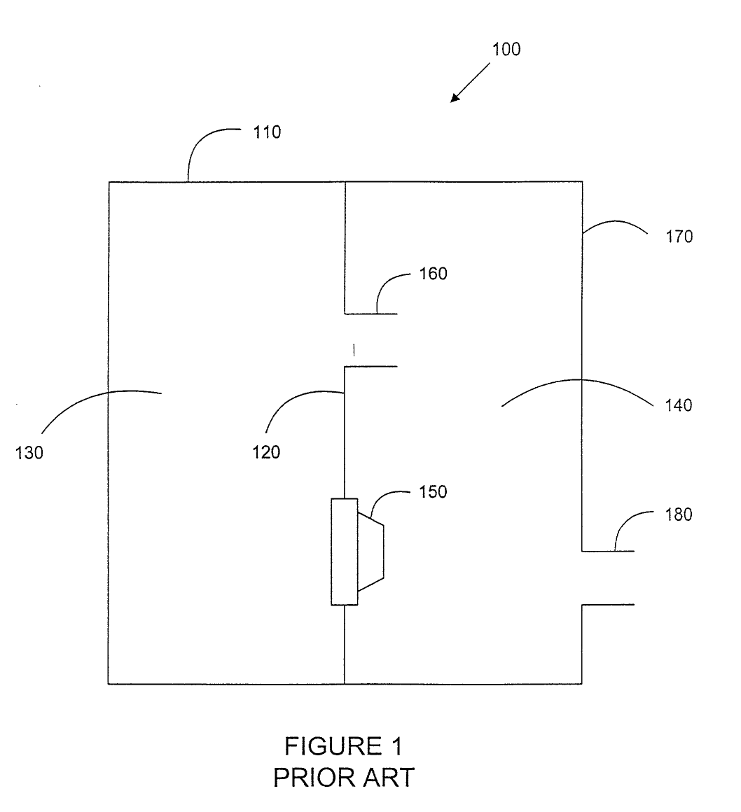

FIGS. 1 through 6, discussed below, and the various embodiments set forth in this patent document to describe the principles of the apparatus and method of the present invention are by way of illustration only and should not be construed in any way to limit the scope of the invention.

FIG. 1 is a schematic diagram of a prior art bass reflex acoustical enclosure 100. Acoustical enclosure 100 comprises a speaker box 110. The interior of speaker box 110 is divided by partitioning wall 120 into two chambers. The first chamber is designated with reference numeral 130 and the second chamber is designated with reference numeral 140. Speaker 150 is mounted within partitioning wall 120. As shown in FIG. 1, speaker 150 is placed within partitioning wall 120 so that the front of speaker 150 has access to first chamber 130. The back of speaker 150 extends into second chamber 140.

Partitioning wall 120 has portions that form a passageway 160. Passageway 160 may also be referred to as a vent 160 or as a port 160. Air within first chamber 130 may pass from first chamber 130 through vent 160 to second chamber 140. Similarly, air within second chamber 140 may pass from second chamber 140 through vent 160 to first chamber 130. Because vent 160 is located within speaker box 110, and because vent 160 connects two interior chambers of speaker box 110, vent 160 is sometimes referred to as an “internal” vent.

Wall 170 of speaker box 110 has portions that form a passageway 180. Passageway 180 may also be referred to as a vent 180 or as a port 180. Air within second chamber 140 may pass from second chamber 140 through vent 180 to the air located outside of speaker box 110. Similarly, air located outside of speaker box 110 may pass through vent 180 to second chamber 140. Because vent 180 connects one interior chamber of speaker box 110 with the air outside of speaker box 110, vent 180 is sometimes referred to as an “external” vent.

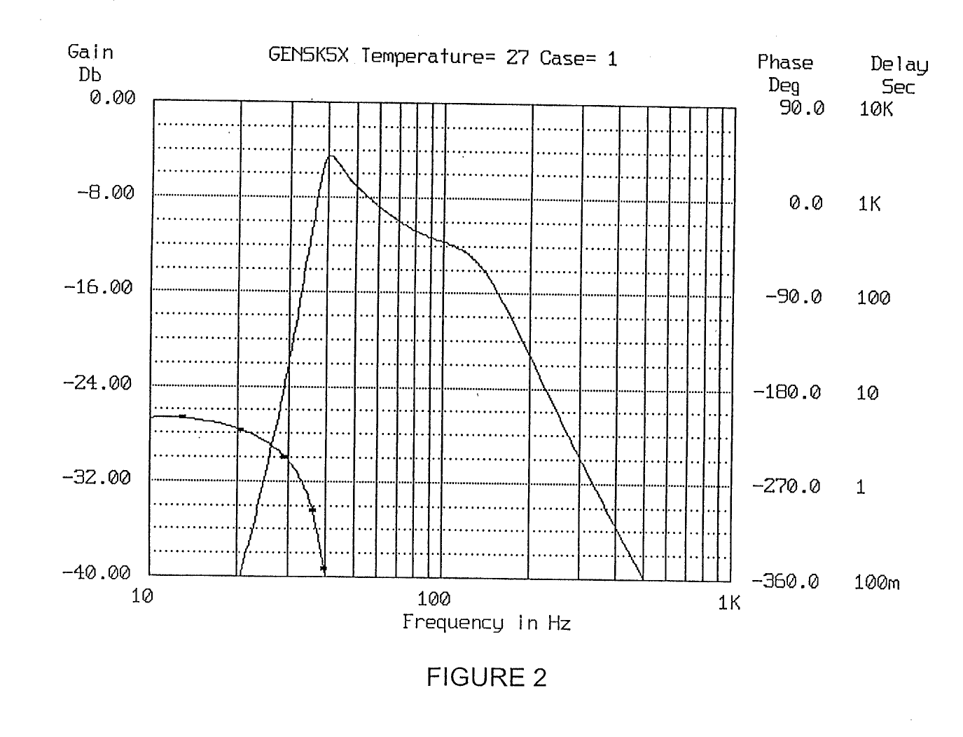

Acoustical enclosure 100 represents a conventional dual chamber single speaker bass reflex acoustical enclosure. FIG. 2 is a frequency response chart showing the gain of the acoustical enclosure 100 as a function of frequency. It may be seen from the curve and the data in the frequency response chart that the enclosure within acoustical enclosure 100 is tuned to forty Hertz (40.0 Hz).

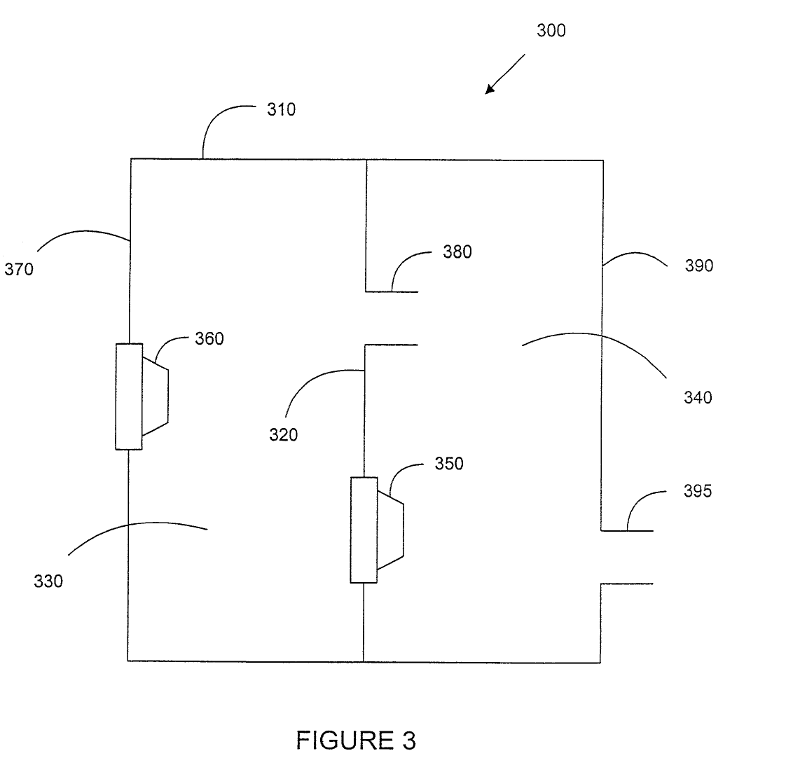

FIG. 3 is a schematic diagram of a bass reflex acoustical 20 enclosure 300 comprising an advantageous embodiment of the present invention. Bass reflex acoustical enclosure 300 comprises two speakers, 350 and 360. It has been determined that the use of a second speaker in bass reflex acoustical enclosure 300 permits the frequency response of bass reflex acoustical enclosure 300 to be extended to the thirty Hertz (30.0 Hz) frequency range if both speakers, 350 and 360, are connected in phase electrically.

Acoustical enclosure 300 comprises a speaker box 310. The interior of speaker box 310 is divided by partitioning wall 320 into two chambers. The first chamber is designated with reference numeral 330 and the second chamber is designated with reference numeral 340. Speaker 350 is mounted within partitioning wall 320. As shown in FIG. 3, speaker 350 is placed within partitioning wall 320 so that the front of speaker 350 has access to first chamber 330. The back of speaker 350 extends into second chamber 340.

Speaker 360 is mounted within wall 370 of speaker box 310. As shown in FIG. 3, speaker 360 is placed within wall 370 so that the front of speaker 360 has access to the air that is external to speaker box 310. The back of speaker 360 extends into first chamber 330.

Partitioning wall 320 has portions that form a passageway 380. Passageway 380 may also be referred to as a vent 380 or as a port 380. Air within first chamber 330 may pass from first chamber 330 through vent 380 to second chamber 340. Similarly, air within second chamber 340 may pass from second chamber 340 through vent 380 to first chamber 330. Because vent 380 is located within speaker box 310, and because vent 380 connects two interior chambers of speaker box 310, vent 380 is sometimes referred to as an “internal” vent.

Wall 390 of speaker box 310 has portions that form a passageway 395. Passageway 395 may also be referred to as a vent 395 or as a port 395. Air within second chamber 340 may pass from second chamber 340 through vent 395 to the air located outside of speaker box 310. Similarly, air located outside of speaker box 310 may pass through vent 395 to second chamber 340. Because vent 395 connects one interior chamber of speaker box 310 with the air outside of speaker box 310, vent 395 is sometimes referred to as an “external” vent.

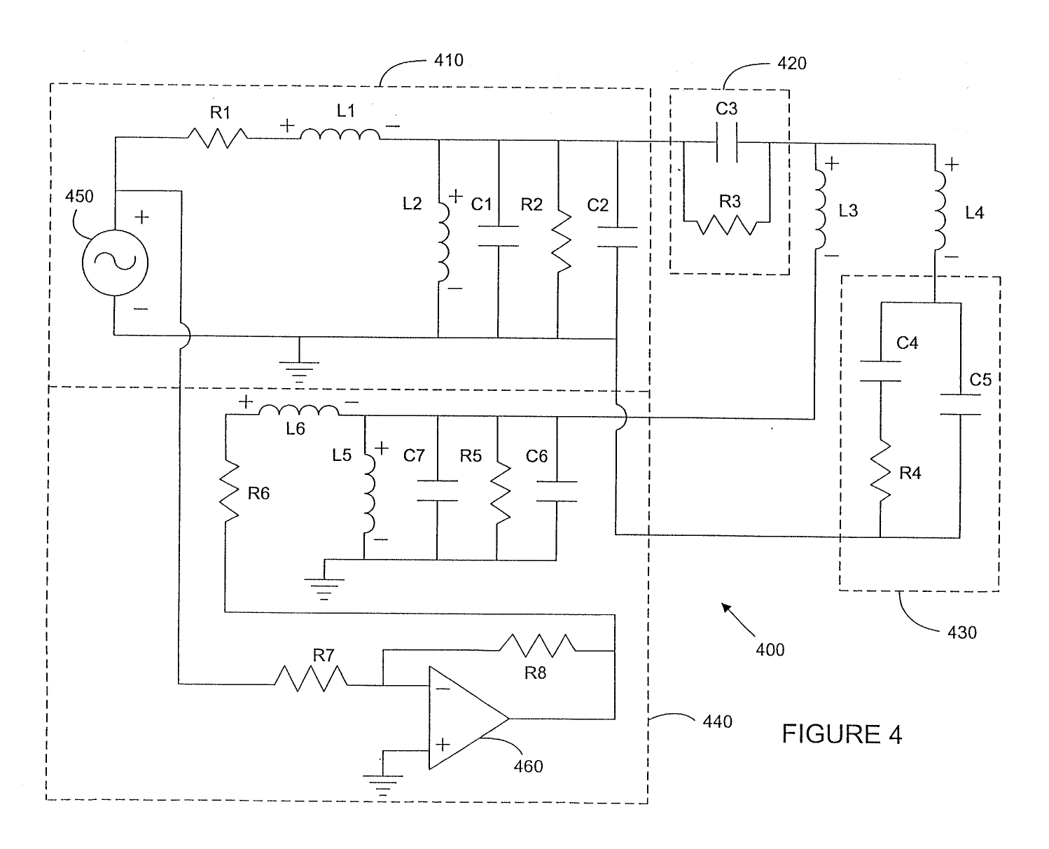

FIG. 4 is a circuit diagram 400 illustrating a model of bass reflex acoustical enclosure 300 of the present invention shown in FIG. 3. Speaker 350 is represented by module 410. Internal vent 380 is represented by module 420. External vent 395 is represented by module 430. Speaker 360 is represented by module 440.

As shown in FIG. 4, module 410 comprises alternating current power source 450 driving a circuit in which resistor R1 and inductor L1 are connected in series and in which inductor L2, capacitor C1, resistor R2, and capacitor C2 are connected in parallel between the negative terminal of inductor L1 and the negative terminal of alternating current power source 450. The negative terminal of alternating current power source 450 is grounded. In one embodiment the circuit elements of module 410 have the following values: R1=7.5 ohms, L1=0.6 millihenries 5 (mH), L2=27.95 millihenries (mH), C1=143.0 microfarads (μF), R2=56.5 ohms, and C2=23.6 microfarads (μF).

Module 410 is coupled to module 420. Module 420 represents internal vent 380. Module 420 comprises capacitor C3 coupled in parallel with resistor R3. In one embodiment the circuit elements of module 420 have the following values: C3=250.0 microfarads (μF) and Re=562.0 ohms.

Module 420 is coupled to two parallel inductors, L3 and L4. In one embodiment the circuit elements L3 and L4 have the following values: L3=21.38 millihenries (mH) and L4=35.64 millihenries (mH). Inductor L4 is coupled to module 430. Module 430 represents external vent 395. Module 430 comprises capacitor C5 coupled in parallel with a series combination of capacitor C4 and resistor R4. In one embodiment the circuit elements of module 430 have the following values: C4=20.56 microfarads (μF), R4=2.187 ohms, and C5=190.6 microfarads (μF). Module 430 is also coupled to the negative terminal of alternating current power source 450.

The positive terminal of alternative current power source 450 is coupled to module 440. Module 440 represents speaker 360. Module 440 comprises a circuit branch in which resistor R6 is coupled in series with inductor L6. Inductor L6 is coupled to a circuit branch comprising inductor L5, capacitor C7, resistor R5, and capacitor C6 coupled in parallel. In one embodiment the circuit elements of module 440 have the following values: C6=23.0 microfarads (μF), R5=56.0 ohms, C7=148.0 microfarads (μF), L5=20.0 millihenries (mH), L6=0.6 millihenries (mH), and R6=7.5 ohms.

Resistor R6 is also coupled to the output of operational amplifier 460. The inverting input of operational amplifier 460 is coupled to the positive terminal of alternating current power source 450 through resistor R7. The non-inverting input of operational amplifier 460 is grounded. Resistor R8 couples the inverting input of operational amplifier 460 to the output of operational amplifier 460. In one embodiment these additional circuit elements of module 440 have the following values: R7=10.0 kilohms and R8=10.0 kilohms.

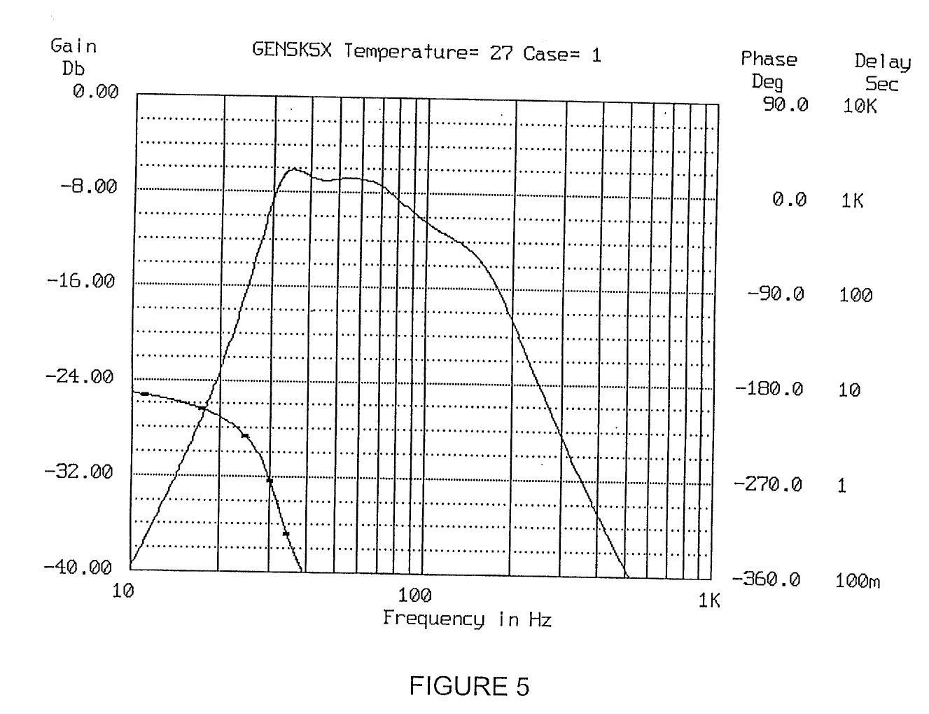

Model 400 electronically models the operation of acoustical enclosure 300. FIG. 5 is a frequency response chart showing the gain of acoustical enclosure 300 of the present invention as a function of frequency. It may be seen from the curve and the data in the frequency response chart that the enclosure within acoustical enclosure 300 is tuned to thirty Hertz (30.0 Hz). The frequency response has been extended from forty Hertz (40.0 Hz) in the prior art acoustical enclosure 100 to thirty Hertz (30.0 Hz) in the acoustical enclosure 300 of the present invention. The extension of the frequency response is due an effective increase in the volume of first chamber 330 due to the presence of speaker 360.

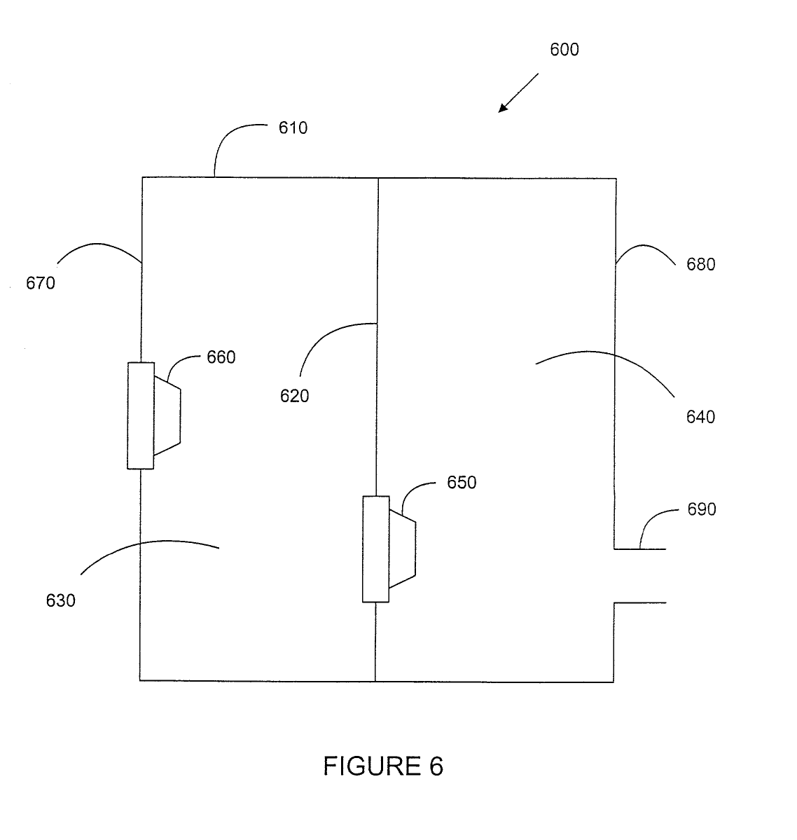

FIG. 6 is a schematic diagram of a bass reflex acoustical enclosure 600 comprising an alternate advantageous embodiment of the present invention. Bass reflex acoustical enclosure 600 comprises two speakers, 650 and 660. It has been determined that the use of a second speaker in bass reflex acoustical enclosure 600 permits the frequency response of bass reflex acoustical enclosure 600 to be extended to the thirty Hertz (30.0 Hz) frequency range if both speakers, 650 and 660, are connected in phase electrically.

Acoustical enclosure 600 comprises a speaker box 610. The interior of speaker box 610 is divided by partitioning wall 620 into two chambers. The first chamber is designated with reference numeral 630 and the second chamber is designated with reference numeral 640. Speaker 650 is mounted within partitioning wall 620. As shown in FIG. 6, speaker 650 is placed within partitioning wall 620 so that the front of speaker 650 has access to first chamber 630. The back of speaker 650 extends into second chamber 640.

Speaker 660 is mounted within wall 670 of speaker box 610. As shown in FIG. 6, speaker 660 is placed within wall 670 so that the front of speaker 660 has access to the air that is external to speaker box 610. The back of speaker 660 extends into first chamber 630.

Unlike acoustical enclosure 300, acoustical enclosure 600 has no passageway or vent within partitioning wall 620. That is, acoustical enclosure 600 has no “internal” vent. First chamber 630 is a closed chamber with respect to the movement of air in and out of first chamber 630.

However, wall 680 of speaker box 610 has portions that form a passageway 690. Passageway 690 may also be referred to as a vent 690 or as a port 690. Air within second chamber 640 may pass from second chamber 640 through vent 690 to the air located outside of speaker box 610. Similarly, air located outside of speaker box 610 may pass through vent 690 to second chamber 640. Because vent 690 connects one interior chamber of speaker box 610 with the air outside of speaker box 610, vent 690 is sometimes referred to as an “external” vent.

Two speakers, 650 and 660, may be used in the alternate embodiment of dual chamber acoustical enclosure 600 even in the absence of an internal vent between first chamber 630 and second chamber 640. Although the present invention has been described in detail with respect to certain embodiments thereof including the illustrative example of a bass reflex acoustical enclosure, the invention is not limited to the described embodiments and modifications thereto. It is understood that those skilled in the art can make various changes, substitutions, modifications, alterations, and adaptations in the present invention without departing from the concept and scope of the invention in its broadest form.

What is claimed is:

1. An acoustical enclosure comprising:
a speaker box comprising walls that enclose an acoustic chamber;
a partitioning wall coupled to interior surfaces of said walls of said speaker box, said partitioning wall dividing said acoustic chamber into a first chamber and into a second chamber;
wherein at least one wall of said walls that enclose said acoustic chamber comprises portions that form an external vent to said second chamber;
a first speaker mounted within said partitioning wall, wherein a front portion of said first speaker has access to said first chamber and a back portion of said first speaker has access to said second chamber; and
a second speaker mounted within one of said walls that enclose said acoustic chamber, wherein a front portion of said second speaker has access to air outside said speaker box and a back portion of said second speaker has access to said first chamber.

2. An acoustical enclosure as claimed in claim 1 wherein said partitioning wall comprises portions that form an internal vent between said first chamber and said second chamber.

3. An acoustical enclosure as claimed in claim 1 wherein said first speaker and said second speaker are connected in phase electrically.

4. An acoustical enclosure as claimed in claim 3 wherein said partitioning wall comprises portions that form an internal vent between said first chamber and said second chamber.

5. An acoustical enclosure as claimed in claim 1 wherein a volume of said first chamber is effectively increased due to the presence of said second speaker within one of said walls that enclose said acoustic chamber.

6. An acoustical enclosure as claimed in claim 5 wherein said partitioning wall comprises portions that form an internal vent between said first chamber and said second chamber.

7. An acoustical enclosure as claimed in claim 1 having a low frequency response range that extends to approximately thirty Hertz.

8. An acoustical enclosure as claimed in claim 7 wherein said partitioning wall comprises portions that form an internal vent between said first chamber and said second chamber.

9. An acoustical enclosure comprising:
a speaker box comprising walls that enclose an acoustic chamber;
a partitioning wall coupled to interior surfaces of said walls of said speaker box, said partitioning wall dividing said acoustic chamber into a first chamber and into a second chamber;
wherein at least one wall of said walls that enclose said acoustic chamber comprises portions that form an external vent to said second chamber;
a first speaker mounted within said partitioning wall, wherein a front portion of said first speaker has access to said first chamber and a back portion of said first speaker has access to said second chamber; and
a second speaker mounted within one of said walls that enclose said acoustic chamber, wherein a front portion of said second speaker has access to air outside said speaker box and a back portion of said second speaker has access to said first chamber;
wherein said second speaker enhances acoustical performance of said acoustic chamber of said acoustical enclosure by extending a range of low frequency response of said acoustical enclosure to approximately thirty Hertz.

10. An acoustical enclosure as claimed in claim 9 wherein said partitioning wall comprises portions that form an internal vent between said first chamber and said second chamber.

11. A method for enhancing acoustical performance of a dual chamber acoustical enclosure, said method comprising the step of:
extending a range of low frequency response of said dual chamber acoustical enclosure to approximately thirty Hertz.

12. A method as claimed in claim 11 wherein said step of extending a range of low frequency response of said dual chamber acoustical enclosure to approximately thirty Hertz comprises the steps of:
placing a first speaker within a partitioning wall that separates a first chamber and a second chamber of said dual chamber acoustical enclosure, wherein a front portion of said first speaker has access to said first chamber and a back portion of said first speaker has access to said second chamber of said dual chamber acoustical enclosure;
placing a second speaker within a wall of said first chamber of said dual chamber acoustical enclosure, wherein a front portion of said second speaker has access to air outside said dual chamber acoustical enclosure and a back portion of said second speaker has access to said first chamber of said dual chamber acoustical enclosure; and
electrically connecting said first speaker and said second speaker in phase.

13. A method as claimed in claim 12 further comprising the step of:
placing an internal vent in said partitioning wall between said first chamber and said second chamber.

14. A method as claimed in claim 12 further comprising the step of:
effectively increasing a volume of said first chamber due to the presence of said second speaker within said wall of said first chamber of said dual chamber acoustical enclosure.

15. A method as claimed in claim 14 further comprising the step of:
placing an internal vent in said partitioning wall between said first chamber and said second chamber.
